(19) United States
(12) Patent Application Publication
(10) Pub. No.: US 2002/0122349 A1
(43) Pub. Date: Sep. 5, 2002

(54) Semiconductor integrated circuit for successively scanning lines of electrodes of an image display apparatus

(76) Inventor: Kazuo Kobayashi, Nagano-ken (JP)

Correspondence Address: HOGAN & HARTSON L.L.P., 500 S. GRAND AVENUE, SUITE 1900, LOS ANGELES, CA, 90071-2611, US

(21) Appl. No.: 10/090,483

(22) Filed: Mar. 1, 2002

(30) Foreign Application Priority Data
Mar. 2, 2001 (JP) 2001-059045(P)

(51) Int. Cl. H01L 31/0336; G11C 8/00

(52) U.S. Cl. 365/233; 257/200; 365/189.12

(57) ABSTRACT

An image display apparatus having a semiconductor integrated circuit for successively scanning lines of scanning electrodes without requiring conversion of the image data even in a circuit layout where scanning electrodes are distributed left and right to increase the number of pixels per unit are, the semiconductor integrated circuit comprising a storage device that receives and stores image data, a display signal generation device that generates a plurality of display signals, a first scanning signal generation device that successively generates scanning signals to be supplied to a first group of scanning electrodes based on a clock signal, a second scanning signal generation device that successively generates scanning signals to be supplied to a second group of scanning electrodes based on the clock signal, and a timing control device that generates the clock signal and generates first and second timing control signals such that the first scanning signal generation device and the second scanning signal generation device generate the scanning signals in a specified order.

### FIELD OF THE INVENTION

The present invention relates to a semiconductor integrated circuit (driver IC) that drives an image display apparatus such as a liquid crystal panel, and more particularly, a semiconductor integrated circuit that is internally provided with RAMs (random access memories) for storing image data that is inputted from an MPU (microprocessor unit). Furthermore, the present invention relates to an image display apparatus using such a semiconductor integrated circuit.

### BACKGROUND OF THE INVENTION

Liquid crystal panels are widely used in display sections of small equipment such as watches and hand-carry type telephones. Moreover, in recent years, while the amount of data to be displayed is increasing, smaller display screens and improvements in the beauty and viewability of the display screens are sought. In a display apparatus such as a liquid crystal panel, the size of each pixel (dot) may be reduced to increase the number of pixels per unit area in order to display a picture with a higher resolution. In order to do this, gaps of the signal electrodes and gaps of the scanning electrodes of the liquid crystal panel need to be narrowed.

FIG. 8 shows one example layout of a conventional liquid crystal display apparatus. In FIG. 8, a plurality of output terminals for outputting display signals S0-S15 from a driver IC (X driver) 103 are connected to a plurality of signal electrodes arranged in a segment direction of a liquid crystal panel 105 through a wiring pattern formed on a substrate 110. Also, a plurality of output terminals for outputting scanning signals C0-C7 from a driver IC (Y driver) 101 are connected to a plurality of scanning electrodes arranged in a common direction of the liquid crystal panel 105 through a wiring pattern formed on the substrate 110. Similarly, a plurality of output terminals for outputting scanning signals C8-C15 from a driver IC (Y driver) 102 are connected to a plurality of scanning electrodes arranged in the common direction of the liquid crystal panel 105.

The X driver 103 is connected to an MPU 106, and a RAM 104 that is built in the X driver 103 stores image data that is supplied from the MPU 106. The X driver 103 generates and outputs display signals S0-S15 based on the image data stored in the RAM 104. Also, the X driver 103 supplies a clock signal that defines the timing to generate the scanning signals to the Y drivers 101 and 102. Based on this, the Y drivers 101 and 102 successively supply scanning signals C0-C7 and C8-C15 to the scanning electrodes of the liquid crystal panel 105, to thereby scan the liquid crystal panel 105.

In such a liquid crystal panel, if the number of pixels per unit area is increased, the pitch of the electrodes also needs to be narrowed. However, in an attempt to narrow the pitch of the electrodes, the wiring pitch of the wiring pattern that is connected to the electrodes reaches its limit, and therefore it is difficult to achieve a higher degree of wiring pattern density.

To solve the problem, a layout shown in FIG. 9 is proposed. In a liquid crystal panel 115 shown in FIG. 9, the gap of the scanning electrodes is reduced by dividing the scanning electrodes into left and right sides as shown in the figure to increase the number of pixels per unit area. In order to do this, a Y driver 111 that supplies scanning signals C0-C7 and a Y driver 112 that supplies scanning signals C8-C15 are disposed respectively on the left side and the right side of the liquid crystal panel 115 in the substrate 120. Such a layout allows the wiring patterns to be connected to the liquid crystal panel 115 in a staggered wiring fashion, such that the wiring pitch does not excessively narrow down.

It is noted that the “staggered wiring” means a wiring to be made when the terminals of the liquid crystal panel 115 are connected to the wiring patterns, wherein the wirings are alternately provided up and down or left and right; for example, odd numbered ones of the scanning lines are wired from the left side and even numbered ones of the scanning lines are wired from the right side. By the staggered wiring, even when the gap between scanning electrodes of the liquid crystal panel 115 may be reduced in half, the wiring pitch on the print substrate may be maintained in a conventional manner.

However, by changing the layout shown in FIG. 8 to the layout shown in FIG. 9, the order of supplying the scanning signals to the scanning electrodes changes. More specifically, because the scanning signals C8-C15 are output from the Y drivers after the scanning signals C0-C7 are output, the lines are successively scanned from the upper side toward the lower side of the liquid crystal panel shown in FIG. 8, but the even numbered lines are scanned after the odd numbered lines are scanned in FIG. 9. To match the display signals with this scanning, data of the RAM 104 in the X driver 103 needs to be modified. Conventionally, the MPU 106 performs such a data conversion. However, the data conversion, when performed by the MPU 106, puts a greater load to the MPU, and takes a longer time. Furthermore, when the scanning signals are supplied in such an order, the pictures do not look natural when they are rewritten.

It is noted that Japanese Laid-open Patent Application HEI 2-1813 describes a color liquid crystal display apparatus including: a color liquid crystal panel in which display cells are formed from the matrix of signal electrodes and scanning electrodes, the display cells are grouped for each unit of three primary colors RGB in the direction of the scanning electrodes to compose display dots, and further the dispositions of the RGB colors for each of the dots are shifted in the unit of each display line such that they are disposed in a staggered lattice form; and a position rotation device that shifts and rotates for each line positional relations between the gradation control signals of the respective RGB colors supplied. However, in this color liquid crystal display apparatus, although the dispositions of the RGB colors are in a staggered lattice form, the wirings of the scanning electrodes are not in a staggered wiring.

Also, Japanese Laid-open Patent Application HEI 8-320664 describes a display apparatus in which X drive circuits and Y drive circuits are composed by a circuit composed of TFTs formed on one substrate, which does not have problems such as the occurrence of an FPN (fix pattern noise) due to variations in the output level caused by variations among IC chips and the shading. However, this display apparatus does not eliminate the load in converting image data or the unnaturalness that occurs at the time of rewriting pictures.

### SUMMARY OF THE INVENTION

In view of the above, it is an object of the present invention to provide a semiconductor integrated circuit and an image display apparatus in which lines can be successively scanned without requiring conversion of the image data even in a layout in which scanning electrodes are distributed left and right to increase the number of pixels per unit area.

To solve the problems described above, a semiconductor integrated circuit in accordance with a first aspect of the present invention pertains to a semiconductor integrated circuit that supplies a plurality of display signals to a corresponding plurality of signal electrodes of an image display apparatus that displays a two-dimensional image, and successively supply scanning signals to a first group of scanning electrodes and a second group of scanning electrodes of the image display apparatus. The semiconductor integrated circuit is equipped with: a storage device that receives and stores image data; a display signal generation device that generates a plurality of display signals to be supplied to the plurality of signal electrodes based on data stored in the storage device; a first scanning signal generation device that successively generates scanning signals to be supplied to the first group of scanning electrodes based on a clock signal that defines a scanning timing of the image display apparatus; a second scanning signal generation device that successively generates scanning signals to be supplied to the second group of scanning electrodes based on the clock signal; and a timing control device that generates the clock signal, and generates a first control signal for controlling the first scanning signal generation device and a second control signal for controlling the second scanning signal generation device such that the first scanning signal generation device and the second scanning signal generation device generate the scanning signals in a specified order.

In the above, the first scanning signal generation device may generate the scanning signals to be supplied to the first group of scanning electrodes based on a logical product of the clock signal and the first control signal, and the second scanning signal generation device may generate the scanning signals to be supplied to the second group of scanning electrodes based on a logical product of the clock signal and the second control signal.

Also, a semiconductor integrated circuit in accordance with a second aspect of the present invention pertains to a semiconductor integrated circuit that supplies a plurality of display signals to a corresponding plurality of signal electrodes of an image display apparatus that displays a two-dimensional image, and successively supply scanning signals to a first group of scanning electrodes and a second group of scanning electrodes of the image display apparatus. The semiconductor integrated circuit is equipped with: a storage device that receives and stores image data; a display signal generation device that generates a plurality of display signals to be supplied to the plurality of signal electrodes based on data stored in the storage device; a timing control device that generates a clock signal that defines a scanning timing of the image display apparatus; a first scanning signal generation device that successively generates scanning signals to be supplied to the first group of scanning electrodes based on the clock signal and a first set potential; and a second scanning signal generation device that successively generates scanning signals to be supplied to the second group of scanning electrodes based on the clock signal and a second set potential.

For example, one of the first and second set potentials may be a power supply potential, and the other one may be a ground potential.

A semiconductor integrated circuit in accordance with a third aspect of the present invention pertains to a semiconductor integrated circuit that supplies a plurality of display signals to a corresponding plurality of signal electrodes of an image display apparatus that displays a two-dimensional image, and successively supply scanning signals to a first group of scanning electrodes and a second group of scanning electrodes of the image display apparatus. The semiconductor integrated circuit is equipped with: a storage device that receives and stores image data; a display signal generation device that generates a plurality of display signals to be supplied to the plurality of signal electrodes based on data stored in the storage device; a first scanning signal generation device that successively generates scanning signals to be supplied to the first group of scanning electrodes based on a first timing control signal; a second scanning signal generation device that successively generates scanning signals to be supplied to the second group of scanning electrodes based on a second timing control signal; and a timing control device that generates the first and second timing control signals such that the first scanning signal generation device and the second scanning signal generation device generate the scanning signals in a specified order.

In the embodiments described above, the first scanning signal generation device and the second scanning signal generation device may alternately generate the scanning signals.

Also, an image display apparatus in accordance with the present invention pertains to an image display apparatus that displays a two-dimensional image, which is equipped with: any one of the semiconductor integrated circuits recited above; a panel having the first group and second group of scanning electrodes disposed such that scanning signals to be supplied to the first group of scanning electrodes are input in one direction of the first group of scanning electrodes, and scanning signals to be supplied to the second group of scanning electrodes are input in the other direction of the second group of scanning electrodes; and a substrate that mounts the panel and the semiconductor integrated circuit thereon.

By the compositions described above, a timing control device is added to a semiconductor integrated circuit such that the order of scanning signals to be output can be changed. Accordingly, even when the scanning electrodes of the liquid crystal panel is provided in a staggered wiring fashion, the lines of the liquid crystal panel can be successively scanned from the top side without changing the data in the RAM. As a result, no extra load is added to the MPU. Also, when pictures are rewritten, each picture can be successively rewritten from its top, which results in a more natural display. The use of such a semiconductor integrated circuit makes it possible to manufacture an image display apparatus that is provided with a liquid crystal panel having a high level of line density without narrowing the wiring pitch on the substrate.

### BRIEF DESCRIPTION OF THE DRAWINGS

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 shows a view of one example layout of an image display apparatus in accordance with one embodiment of the present invention.

FIG. 2 shows a block diagram of a composition of a semiconductor integrated circuit in accordance with a first embodiment of the present invention.

FIG. 3 shows a timing chart of a variety of signals in the semiconductor integrated circuit shown in FIG. 2.

FIG. 4 shows a block diagram of a composition of a semiconductor integrated circuit in accordance with a second embodiment of the present invention.

FIG. 5 shows a timing chart of a variety of signals in the semiconductor integrated circuit shown in FIG. 4.

FIG. 6 shows a block diagram of a composition of a semiconductor integrated circuit in accordance with a third embodiment of the present invention.

FIG. 7 shows a timing chart of a variety of signals in the semiconductor integrated circuit shown in FIG. 6.

FIG. 8 shows a view of a layout of a conventional liquid crystal display apparatus in which a liquid crystal panel and driver ICs are wired in the normal wiring.

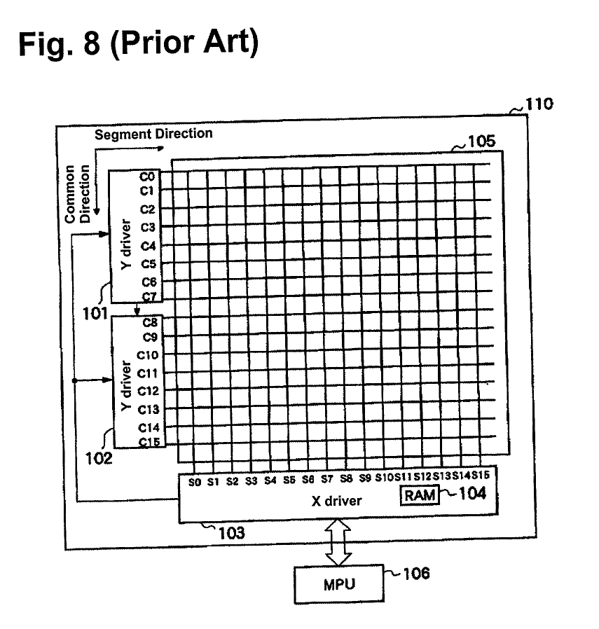

FIG. 9 shows a view of a layout of a conventional liquid crystal display apparatus in which a liquid crystal panel and driver ICs are wired in the staggered wiring.

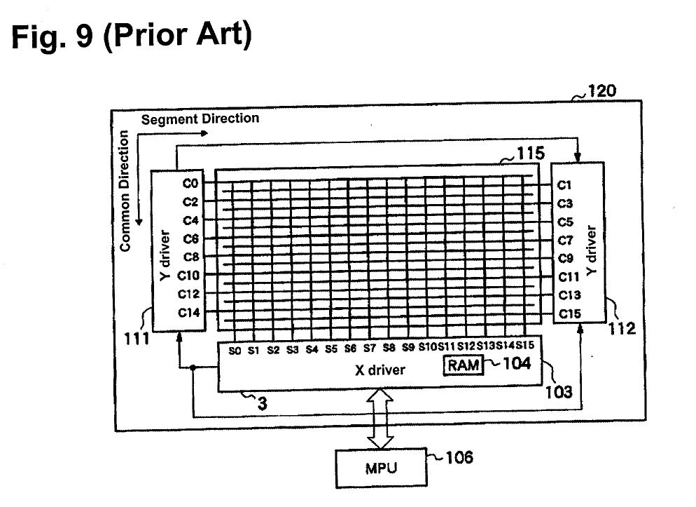

### DETAILED DESCRIPTION OF THE INVENTION

Embodiments of the present invention are described below with reference to the accompanying drawings. It is noted that the same components are referred to by the same reference numbers and their description is omitted.

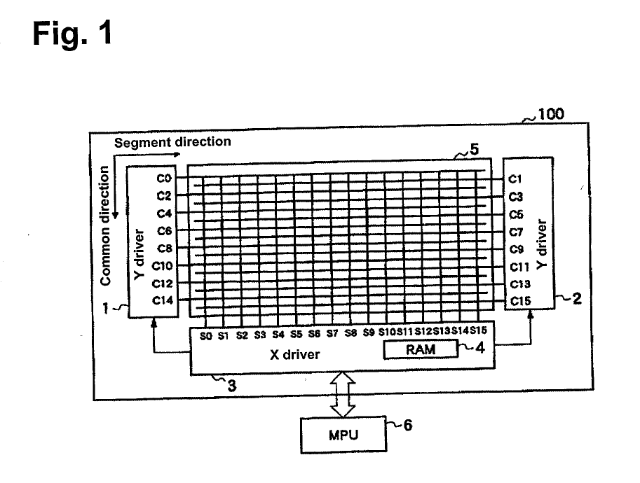

FIG. 1 shows an example layout of an image display apparatus in accordance with one embodiment of the present invention. In the present embodiment, a liquid crystal display apparatus is described as an example. It is noted that, in the present application, a substrate may mean a transparent insulation substrate, a printed substrate, a flexible substrate or the like, which can be provided with a liquid crystal panel and driver ICs and electrically wired. In the present embodiment, a glass substrate is used.

As shown in FIG. 1, an image display apparatus in accordance with the present embodiment includes a substrate 100, driver ICs 1-3 mounted on the substrate 100, and a liquid crystal panel 5. The driver ICs (Y drivers) 1 and 2 output scanning signals for driving the liquid crystal panel 5, and the driver IC (X driver) 3 outputs display signals for driving the liquid crystal panel 5. Also, a MPU (microprocessor unit) 6 is connected to the X driver 3. Image data representative of image information, addresses that control data storage regions, and a variety of control signals including write control signals and read control signals, which are output from the MPU 6, are input in the X driver 6.

The liquid crystal panel 5 has a plurality of regions in a segment direction and also a plurality of regions in a common direction. By specifying one of the regions in the segment direction and one of the regions in the common direction, one pixel (dot) is specified. As one example, the liquid crystal panel 5 has 160 regions in the segment direction and 120 regions in the common direction. In this case, the liquid crystal panel 5 has 160×120 pixels.

To apply voltage to these regions, the liquid crystal panel 5 is provided with a plurality of signal electrodes arranged in the segment direction and a plurality of scanning electrodes arranged in the common direction. The signal electrodes are connected to a plurality of output terminals provided in the X driver 3, and the scanning electrodes are connected to a plurality of output terminals provided in the Y drivers 1 and 2.

As shown in FIG. 1, the X driver 3 includes a RAM (random access memory) that stores image data that is supplied from the MPU 6. The X driver generates display signals S0-S15 to be supplied to the plurality of signal electrodes arranged in the segment direction of the liquid crystal panel 5. Also, the Y drivers 1 and 2 generate scanning signals C0, C2, . . . , C14 and C1, C3, . . . , C15 that scan the liquid crystal panel 5 according to line pulses that are supplied from the X driver 3, and supply the same to the plurality of scanning electrodes arranged in the common direction of the liquid crystal panel 5. Here, as shown in FIG. 1, the wiring is made such that the scanning signals C0, C2, . . . , C14 are input in the liquid crystal panel 5 from the left side thereof in the figure, and the scanning signals C1, C3, . . . , C15 are input in the liquid crystal panel 5 from the right side thereof in the figure. Also, the wiring is made such that the display signals S9, S1, . . . , S15 are input in the liquid crystal panel 5 from the bottom side thereof in the figure. It is noted that transparent material is used for the wiring.

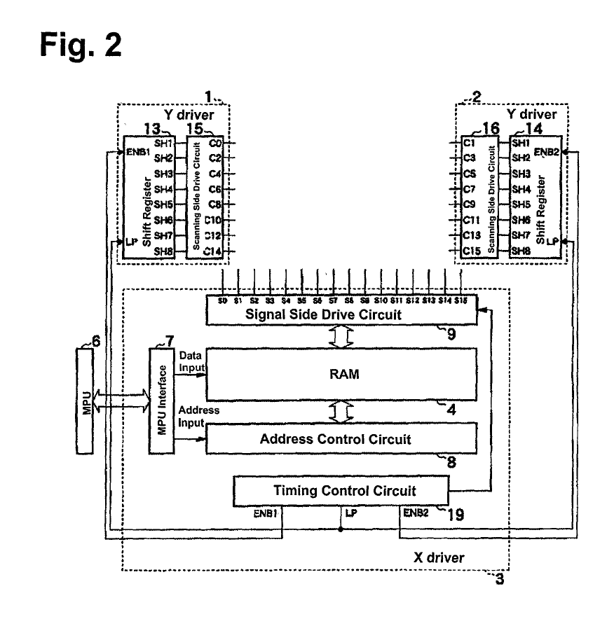

FIG. 2 shows a structure of a semiconductor integrated circuit in accordance with a first embodiment of the present invention. As shown in FIG. 2, the X driver 3 includes an MPU interface 7 for connecting to the MPU 6, a RAM 4, an address control circuit 8 that controls storage regions of image data in the RAM 4, and a signal side driver circuit 9 that supplies display signals to the liquid crystal panel. Furthermore, the X driver 3 includes a timing control circuit 19 that controls output timings of the display signals and the scanning signals.

The RAM 4 stores image data that is input from the MPU 6. Storage regions for the image data in the RAM 4 are designated by the address control circuit 8 according to addresses that are input from the MPU 6. Also, the signal side driver circuit 9 generates the display signals S0, S1, . . . , S15 based on the image data that is input from the RAM 4.

The timing control circuit 19 controls output timings of the display signals at the signal side driver circuit 9. Also, the timing control circuit 19 controls output timings of the scanning signals at the Y drivers 1 and 2. For this, the timing control circuit 19 supplies line pulses LP, which are clock signals that determine timings of the line scanning, to the Y drivers 1 and 2, and supplies a control signal ENB1 to the Y driver 1 and a control signal ENB2 to the Y driver 2 to control the order of outputting the scanning signals C0-C15 depending on the normal wiring or the staggered wiring.

The Y driver 1 includes a shift register 13 and a scanning side drive circuit 15, and the Y driver 2 includes a shift register 14 and a scanning side drive circuit 16. In the case of the staggered wiring, the shift register 13 successively outputs signals to output terminals SH1-SH8 in synchronism with odd numbered pulses among the line pluses LP according to the control signal ENB1, and the shift register 14 successively outputs signals to output terminals SH1-SH8 in synchronism with even numbered pulses among the line pluses LP according to the control signal ENB2. In the case of the normal wiring, the shift register 13 successively outputs signals to the output terminals SH1-SH8 in synchronism with each of the pulses among the line pulses LP, and then the shift register 14 successively outputs signals to the output terminals SH8-SH1 in synchronism with each of the pulses among the line pulses LP.

The case in the staggered wiring is described as follows. The scanning side drive circuit 15 successively outputs scanning signals C0, C2, . . . , C14 to be supplied to the odd numbered ones of the scanning electrodes based on the signals output from the output terminals SH1-SH8 of the shift register 13. In the mean time, the scanning side drive circuit 16 successively outputs scanning signals C1, C3, . . . , C15 to be supplied to the even numbered ones of the scanning electrodes based on the signals output from the output terminals SH1-SH8 of the shift register 14.

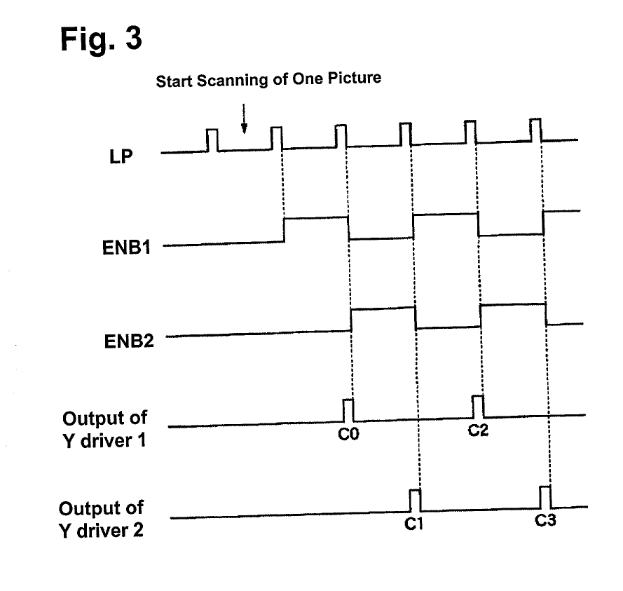

Next, operations of the driver ICs in accordance with the present embodiment are described with reference to FIG. 2 and FIG. 3. FIG. 3 shows a timing chart of a variety of signals in the semiconductor integrated circuit shown in FIG. 2.

FIG. 3 shows a timing relation among the line pulses LP that are output from the timing control circuit 19, the control signals ENB1 and ENB2 that are output from the timing control circuit 19 to the respective Y drivers 1 and 2, and the scanning signals that are output from the respective Y drivers 1 and 2.

As shown in FIG. 3, when the scanning of one picture is started, the timing control circuit 19 alternately sets the control signals ENB1 and ENB2 at high levels in synchronism with the line pulses. In the Y driver 1, the shift register 13, in synchronism with the clock signal that is input while the control signal ENB 1 is at high level, successively outputs signals to the output terminals SH1-SH8. Based on this, the signal side driver circuit 15 successively outputs the scanning signals C0, C2, . . . , C14 to be supplied to the odd numbered ones of the scanning electrodes. Also, the shift register 14, in synchronism with the clock signal that is input while the control signal ENB2 is at high level, successively outputs signals to the output terminals SH1-SH8. Based on this, the signal side driver circuit 16 successively outputs the scanning signals C1, C3, . . . , C15 to be supplied to the even numbered ones of the scanning electrodes. Such an operation can be achieved by taking a logical product of the control signal and the clock signal.

As a result, the scanning signals are alternately output from the scanning side drive circuits 15 and 16 in the order of C0, C1, C2, C3, . . . , C14 and C15, such that the liquid crystal panel 5 (see FIG. 1) is successively scanned from the upper side toward the lower side in the figure.

Next, a semiconductor integrated circuit in accordance with a second embodiment of the present invention is described. In the present embodiment, the order of outputting the scanning signals C0-C15 is controlled by providing certain wirings in advance that apply to the Y drivers potentials that are set according to whether one or the other of the Y drivers is disposed on the left side or the right side of the liquid crystal panel. Further, potentials that are set according to whether the normal wiring is used or the staggered wiring is used may be applied to the driver ICs.

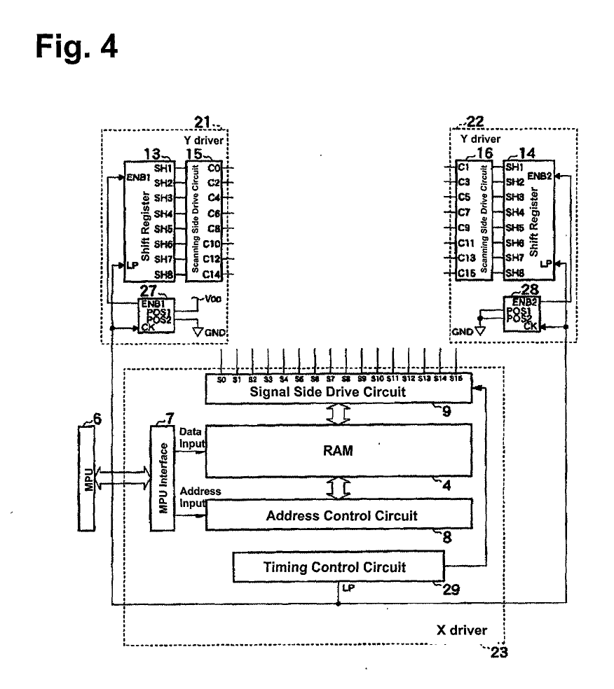

FIG. 4 shows a composition of the semiconductor integrated circuit in accordance with the present embodiment. As shown in FIG. 4, an X driver 23 includes an MPU interface 7, a RAM 4 and a signal side driver circuit 9. Further, the X driver 23 includes a timing control circuit 29 that controls output timings of the display signals and the scanning signals.

A Y driver 21 includes a shift register 13, a shift register control circuit 27 that controls the operation of the shift register, and a scanning side drive circuit 15 that outputs scanning signals to the scanning electrodes of the liquid crystal panel based on output signals of the shift register 13. Also, a Y driver 22 includes a shift register 14, a shift register control circuit 28 that controls the operation of the shift register, and a scanning side drive circuit 16 that outputs scanning signals to the scanning electrodes of the liquid crystal panel based on output signals of the shift register 14.

As a potential POS1 that is set according to whether the Y driver is disposed on the left side or the right side of the liquid crystal panel, the power supply potential V_{DD} that indicates the “left side” is connected to the shift register control circuit 27, and the ground potential GND that indicates the “right side” is connected to the shift register control circuit 28. Also, as a potential POS2 that is set according to whether the normal wiring is used or the staggered wiring is used, the ground potential GND that indicates the “staggered wiring” is connected to the shift register control circuits 27 and 28. The shift register control circuits 27 and 28 generate the control signals ENB1 and ENB2, respectively, based on the set potentials and the line pulses LP. It is noted that, to give a scanning start timing for one picture, for example, a special pulse may be supplied as the line pulse LP to the shift register control circuits 27 and 28.

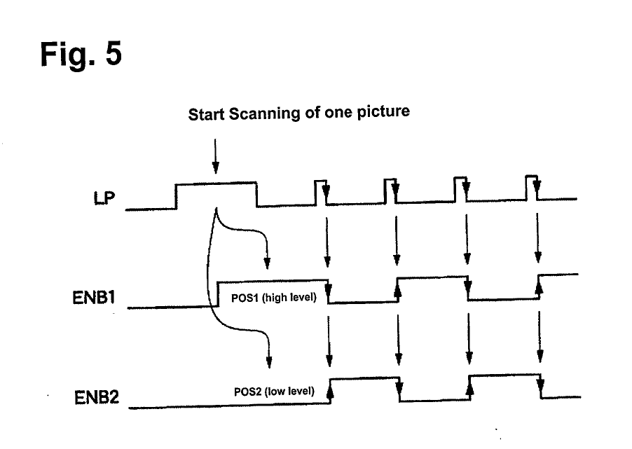

Next, operations of the driver ICs in accordance with the present embodiment are described with reference to FIG. 4 and FIG. 5. FIG. 5 shows a timing chart of a variety of signals in the semiconductor integrated circuit shown in FIG. 4.

The timing control circuit 29 included in the X driver 23 outputs once a special pulse (a pulse with a long duration in FIG. 5) that indicates a start of scanning of one picture, and then repeatedly outputs normal pulses indicating scanning timings. The shift register control circuits 27 and 28, upon application of the pulse with a long duration, set the potentials of the POS 1 as outputs. As a result, the output of the shift register control circuit 27 becomes to be at high level, and the output of the shift register control circuit 28 becomes to be at low level. Thereafter, the shift register control circuits 27 and 28 invert their outputs at falling edges of the normal pulses. In this manner, the control signals ENB1 and ENB2 are generated. The operations of the shift registers 13 and 14 and the scanning side drive circuits 15 and 16 are the same as those of the first embodiment. It is noted that, when the power supply potential V_{DD} that indicates the “normal wiring” is connected as the set potential POS2, for example, signals that become to be at high level during required scanning periods are output as the control signals ENB1 and ENB2.

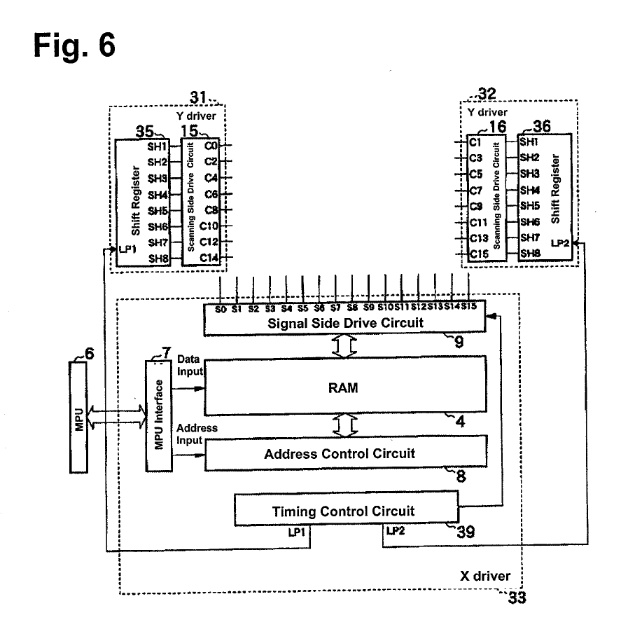

Next, a semiconductor integrated circuit in accordance with a third embodiment of the present invention is described. As shown in FIG. 6, an X driver 33 includes an MPU interface 7, a RAM 4, an address control circuit 8, and a signal side driver circuit 9. Further, the X driver 33 includes a timing control circuit 39.

The timing control circuit 39 controls output timings of the display signals at the signal side driver circuit 9. Also, the timing control circuit 39 controls output timings of the scanning signals at the Y drivers 31 and 32. For this purpose, the timing control circuit 39 outputs to the Y driver 31 line pulses LP1 that are clock signals that determine timings for the line scanning at the Y driver 31, and outputs to the Y driver 32 line pulses LP2 that are clock signals that determine timings for the line scanning at the Y driver 32.

The Y driver 31 includes a shift register 35 and a scanning side drive circuit 15, and the Y driver 32 includes a shift register 36 and a scanning side drive circuit 16. The shift register 35 successively outputs signals to the output terminals SH1-SH8 in synchronism with the line pulses LP1. The shift register 36 successively outputs signals to the output terminals SH1-SH8 in synchronism with the line pulses LP2.

The scanning side drive circuit 15 successively outputs scanning signals C0, C2, . . . , C14 to be supplied to the odd numbered ones of the scanning electrodes based on the signals output from the output terminals SH1-SH8 of the shift register 35. In the mean time, the scanning side drive circuit 16 successively outputs scanning signals C1, C3, . . . , C15 to be supplied to the even numbered ones of the scanning electrodes based on the signals output from the output terminals SH1-SH8 of the shift register 36.

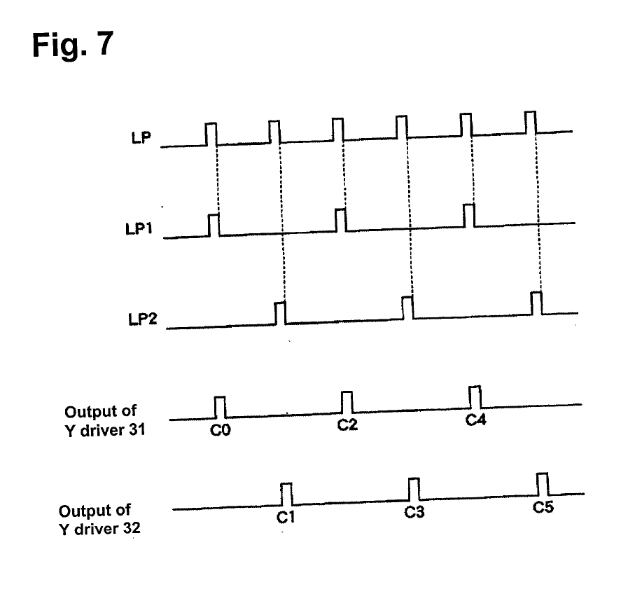

Next, operations of the driver ICs in accordance with the present embodiment are described with reference to FIG. 6 and FIG. 7. FIG. 7 shows a timing chart of a variety of signals in the semiconductor integrated circuit shown in FIG. 6.

FIG. 7 shows a timing relation among the line pulses LP that are clock signals that determine timings of the line scanning, the timing control signals LP1 and LP2 that are supplied from the timing control circuit 39 to the Y drivers 31 and 32, and the scanning signals that are output from the Y drivers 31 and 32.

The timing control circuit 39, when the scanning is started for one picture, alternately outputs the timing control signals LP1 and LP2 in synchronism with the line pulses LP. The shift register 35 successively outputs signals from the output terminals SH1-SH8 in synchronism with the timing control signal LP1 being input. Based on this, the scanning side drive circuit 15 successively outputs the scanning signals C0, C2, . . . to be supplied to the odd numbered ones of the scanning electrodes. Also, the shift register 36 successively outputs signals from the output terminals SH1-SH8 in synchronism with the timing control signal LP2 being input. Based on this, the scanning side drive circuit 16 successively outputs the scanning signals C1, C3, . . . to be supplied to the even numbered ones of the scanning electrodes. As shown in FIG. 7, the timing control signals LP1 and LP2 are alternately output, such that the scanning signals are output in the order of C9, C1, C2, C3, . . . , and therefore the liquid crystal panel 5 (see FIG. 1) is successively scanned from the upper side toward the lower side.

As described above, in accordance with the present invention, a timing control device is added to a semiconductor integrated circuit such that the order of scanning signals to be output can be changed. Accordingly, even when the scanning electrodes of the liquid crystal panel is provided in a staggered wiring, the lines of the liquid crystal panel can be successively scanned from the top side without changing the data in the RAM. As a result, no extra load is added to the MPU. Also, when pictures are rewritten, each picture can be successively rewritten from its top, which results in a more natural display of the picture. The use of such a semiconductor integrated circuit makes it possible to manufacture an image display apparatus that is provided with a liquid crystal panel having a high level of line density without narrowing the wiring pitch on the substrate.

What is claimed is:

1. A semiconductor integrated circuit that supplies a plurality of display signals to a corresponding plurality of signal electrodes of an image display apparatus that displays a two-dimensional image, and successively supplies scanning signals to a first group of scanning electrodes and a second group of scanning electrodes of the image display apparatus, the semiconductor integrated circuit comprising:
a storage device that receives and stores image data;
a display signal generation device that generates the plurality of display signals to be supplied to the plurality of signal electrodes based on data stored in the storage device;
a first scanning signal generation device that successively generates scanning signals to be supplied to the first group of scanning electrodes based on a clock signal that defines a scanning timing of the image display apparatus;
a second scanning signal generation device that successively generates scanning signals to be supplied to the second group of scanning electrodes based on the clock signal; and
a timing control device that generates the clock signal, and generates a first timing control signal for controlling the first scanning signal generation device and a second timing control signal for controlling the second scanning signal generation device such that the first scanning signal generation device and the second scanning signal generation device generate the scanning signals in a specified order.

2. A semiconductor integrated circuit according to claim 1, wherein the first scanning signal generation device generates the scanning signals to be supplied to the first group of scanning electrodes based on a logical product of the clock signal and the first timing control signal, and the second scanning signal generation device generates the scanning signals to be supplied to the second group of scanning electrodes based on a logical product of the clock signal and the second timing control signal.

3. A semiconductor integrated circuit that supplies a plurality of display signals to a corresponding plurality of signal electrodes of an image display apparatus that displays a two-dimensional image, and successively supply scanning signals to a first group of scanning electrodes and a second group of scanning electrodes of the image display apparatus, the semiconductor integrated circuit comprising:
a storage device that receives and stores image data;
a display signal generation device that generates the plurality of display signals to be supplied to the plurality of signal electrodes based on data stored in the storage device;
a timing control device that generates a clock signal that defines a scanning timing of the image display apparatus;
a first scanning signal generation device that successively generates scanning signals to be supplied to the first group of scanning electrodes based on the clock signal and a first set potential; and
a second scanning signal generation device that successively generates scanning signals to be supplied to the second group of scanning electrodes based on the clock signal and a second set potential.

4. A semiconductor integrated circuit according to claim 3, wherein one of the first and second set potentials is a power supply potential, and the other one is a ground potential.

5. A semiconductor integrated circuit that supplies a plurality of display signals to a corresponding plurality of signal electrodes of an image display apparatus that displays a two-dimensional image, and successively supply scanning signals to a first group of scanning electrodes and a second group of scanning electrodes of the image display apparatus, the semiconductor integrated circuit comprising:
a storage device that receives and stores image data;
a display signal generation device that generates the plurality of display signals to be supplied to the plurality of signal electrodes based on data stored in the storage device;
a first scanning signal generation device that successively generates scanning signals to be supplied to the first group of scanning electrodes based on a first timing control signal;
a second scanning signal generation device that successively generates scanning signals to be supplied to the second group of scanning electrodes based on a second timing control signal; and
a timing control device that generates the first and second timing control signals such that the first scanning signal generation device and the second scanning signal generation device generate the scanning signals in a specified order.

6. A semiconductor integrated circuit according to any one of claims 1, 3, and 5, wherein the first scanning signal generation device and the second scanning signal generation device alternately generate the scanning signals.

7. An image display apparatus that displays a two-dimensional image, comprising:
a semiconductor integrated circuit recited in any one of claims 1, 3, and 5;
a panel having the first group and second group of scanning electrodes disposed such that scanning signals to be supplied to the first group of scanning electrodes are input in one direction of the first group of scanning electrodes, and scanning signals to be supplied to the second group of scanning electrodes are input in the other direction of the second group of scanning electrodes; and
a substrate that mounts the panel and the semiconductor integrated circuit thereon.

8. The semiconductor integrated circuit according to anyone of claims 1, 3, and 5, wherein the first scanning signal generation device comprises:
a first shift register; and
a first driver circuit coupled to the first shift register, said first shift register receiving the clock signal and/or the first timing control signal for successively generating a drive signal to one of a plurality of input terminals of said first driver circuit, said first driver circuit then successively outputting a scanning signal to predetermined scanning electrodes of the first group of scanning electrodes.

9. The semiconductor integrated circuit according to anyone of claims 1, 3, and 5, wherein the second scanning signal generation device comprises:
a second shift register; and
a second driver circuit coupled to the second shift register, said second shift register receiving the clock signal and/or the second timing control signal for successively generating a drive signal to one of a plurality of input terminals of said second driver circuit, said second driver circuit then successively outputting a scanning signal to predetermined scanning electrodes of the second group of scanning electrodes.

10. The semiconductor integrated circuit according to claims 3, wherein the first scanning signal generation device comprises a first control circuit for generating a first control signal based on the first set potential, and the second scanning signal generation device comprises a second control circuit for generating a second control signal based on the second set potential, said first and second scanning signal generation device generating scanning signals based on a logical product of the clock signal and the first and second control signals, respectively.

11. A method for supplying a plurality of display signals and a plurality of scanning signals to an image display apparatus from a semiconductor integrated circuit, the method comprising the steps of:
receiving image data by the semiconductor integrated circuit;
generating the plurality of display signals based on the image data and supplying the plurality of display signals to signal electrodes of the image display apparatus;
generating first and second control signals respectively for first and second drivers of the semiconductor integrated circuit;
alternately generating scanning signals by the first and second drivers based on the first and second control signals; and
supplying the scanning signals in succession to scanning electrodes of the image display apparatus.

12. The method according to claim 11, wherein the step of generating first and second control signals comprises:
generating a clock signal; and
alternately generating the first and second control signals based on the clock signal.

13. The method according to claim 11, wherein the step of generating first and second control signals comprises:
generating a clock signal; and
alternately generating first and second timing control signals, said first and second drivers generating the scanning signals based on a logical product of the clock signal and the first and second timing control signals, respectively.

14. The method according to claim 11, wherein the step of generating first and second control signals comprises:
generating a clock signal; and
alternately generating first and second timing control signals respectively based on a first and a second set potential, said first and second drivers generating the scanning signals based on a logical product of the clock signal and the first and second timing control signals, respectively.

15. The method according to claim 14, wherein the first set potential is a power supply potential and the second set potential is a ground potential.
